(19) United States
(12) Patent Application Publication
(10) Pub. No.: US 2017/0239919 A1
(43) Pub. Date: Aug. 24, 2017

(54) GLASS LAMINATE, METHOD FOR PRODUCING SAME AND METHOD FOR MANUFACTURING ELECTRONIC DEVICE

(71) Applicant: Asahi Glass Company, Limited, Chiyoda-ku (JP)

(72) Inventors: Tatsuzo MIYAGOE, Chiyoda-ku (JP); Hideaki MIYAZAWA, Chiyoda-ku (JP); Takatoshi YAOITA, Chiyoda-ku (JP)

(73) Assignee: Asahi Glass Company, Limited, Chiyoda-ku (JP)

(21) Appl. No.: 15/590,039

(22) Filed: May 9, 2017

Related U.S. Application Data
(63) Continuation of application No. PCT/JP2015/081996, filed on Nov. 13, 2015.

(30) Foreign Application Priority Data
Nov. 21, 2014 (JP) 2014-236517

(51) Int. Cl. B32B 17/10; H01L 51/50; H01L 51/00; C03C 17/22; C03C 17/30

(52) U.S. Cl. CPC B32B 17/10798; C03C 17/22; C03C 17/30; H01L 51/0096; H01L 51/50; B32B 17/10807; C03C 2217/282; G02F 2001/133302

(57) ABSTRACT

To provide a glass laminate of which an increase of the peel strength between a glass substrate and a silicone resin layer is suppressed even after a high temperature heat treatment, and from which the glass substrate can readily be separated. A glass laminate comprising a support substrate, a silicone resin layer and a glass substrate in this order, with a peel strength at the interface between the support substrate and the silicon resin layer higher than the peel strength at the interface between the silicone resin layer and the glass substrate, wherein a silicone resin in the silicone resin layer is a cured product obtained by reacting an alkenyl-group containing organopolysiloxane (A) and a hydrogen polysiloxane (B) having a hydrosilyl group, and the mixing molar ratio of the hydrosilyl groups in the hydrogen polysiloxane (B) to the alkenyl groups in the alkenyl group-containing organopolysiloxane (A) (that is, number of mols of hydrosilyl groups/number of mols of alkenyl groups) is from 0.15/1 to 0.65/1.

### TECHNICAL FIELD

The present invention relates to a glass laminate and a method for producing it. Particularly, it relates to a glass laminate having a silicone resin layer obtained by reacting an alkenyl group-containing organopolysiloxane and a hydrogen polysiloxane with their mixing molar ratio adjusted to be within a specific range, and a method for producing it.

The present invention further relates to a method for producing an electronic device using the glass laminate.

### BACKGROUND ART

In recent years, reduction in thickness and weight saving of devices (electronic devices) such as a solar battery (PV), a liquid crystal panel (LCD) and an organic EL panel (OLED) are in progress, and reduction in thickness of a glass substrate used for such devices is in progress. If the strength of a glass substrate decreases due to the reduction in thickness, handling efficiency of the glass substrate decreases in a device production method.

In recent years, to solve the above problems, a method has been proposed in which a glass laminate having a glass substrate and a reinforcing plate laminated is prepared, an electronic device component such as a display device is formed on the glass substrate of the glass laminate, and the reinforcing plate is separated from the glass substrate (for example, Patent Document 1). The reinforcing plate comprises a support plate and a silicone resin layer fixed on the support plate, and the silicone resin layer and the glass substrate are removably bonded. The support plate separated from the glass substrate by separation at the interface between the silicone resin layer and the glass substrate of the glass laminate, may be laminated on a new glass substrate and recycled for a glass laminate.

In Patent Document 1, for formation of the silicone resin layer, a polyorganosiloxane having a vinyl group and hydrogen polysiloxane having a hydrosilyl group are used, and Patent Document 1 discloses in Examples the mixing ratio of them to be adjusted so that the molar ratio of the hydrosilyl groups to the vinyl groups would be about 1/1.

### PRIOR ART DOCUMENTS

### Patent Documents

Patent Document 1: WO2007/018028

### DISCLOSURE OF INVENTION

### Technical Problem

In recent years, along with further reduction in thickness of an electronic device, a glass substrate used becomes thinner, and further improvement in its handling efficiency is required. Accordingly, it is desired that after formation of an electronic device component on a glass substrate in a glass laminate under high temperature conditions, when the glass substrate is separated from the glass laminate, the glass substrate will more readily be separated. When the glass substrate can more readily be separated, the glass substrate is less likely to be damaged.

The present inventors have evaluated releasability of a glass substrate using a glass laminate comprising a silicone resin layer formed by using a polyorganosiloxane having an alkenyl group and a hydrogen polysiloxane having a hydrosilyl group with a mixing ratio of them adjusted to be within the range disclosed in Patent Document 1, with reference to the above-described Patent Document 1. Although the releasability satisfied the level previously required, it does not achieve a higher level required in recent years, and further improvement in the releasability of a glass substrate is required.

Under these circumstances, it is an object of the present invention to provide a glass laminate of which an increase of the peel strength between the glass substrate and the silicone layer is suppressed even after a high temperature heat treatment, and from which the glass substrate can readily be separated, and a method for producing it.

Another object of the present invention is to provide a method for producing an electronic device using the glass laminate.

### Solution to Problem

The present inventors have conducted extensive studies to achieve the above objects and as a result, found that desired effects can be obtained by adjusting the mixing molar ratio of hydrosilyl groups in the hydrogen polysiloxane to the alkenyl groups in the alkenyl group-containing organopolysiloxane used, and accomplished the present invention.

That is, according to a first embodiment of the present invention, there is provided a glass laminate comprising a support substrate, a silicone resin layer and a glass substrate in this order, with a peel strength at the interface between the support substrate and the silicone resin layer higher than the peel strength at the interface between the silicone resin layer and the glass substrate, wherein a silicone resin in the silicone resin layer is a cured product obtained by reacting an alkenyl-group containing organopolysiloxane (A) and a hydrogen polysiloxane (B) having a hydrosilyl group, and the mixing molar ratio of the hydrosilyl groups in the hydrogen polysiloxane (B) to the alkenyl groups in the alkenyl group-containing organopolysiloxane (A) (that is, number of mols of hydrosilyl groups/number of mols of alkenyl groups) is from 0.15/1 to 0.65/1.

In the first embodiment, it is preferred that the alkenyl group-containing organopolysiloxane (A) has a number average molecular weight of from 500 to 9,000.

According to the first embodiment, it is preferred that the silicone resin layer is a layer obtained by applying a curing treatment to a layer obtained by applying a curable resin composition containing the alkenyl group-containing organopolysiloxane (A) and the hydrogen polysiloxane (B) with a mixing molar ratio of the hydrosilyl groups in the hydrogen polysiloxane (B) to the alkenyl groups in the alkenyl group-containing organopolysiloxane (A) (number of mols of hydrosilyl groups/number of mols of alkenyl groups) of from 0.15/1 to 0.65/1.

According to the first embodiment, it is preferred that the curable resin composition further contains a solvent.

According to the first embodiment, it is preferred that the solvent has a boiling point of from 30 to 280° C.

According to the first embodiment, it is preferred that the Hildebrand solubility parameter (SP value) of the solvent is preferably not more than 14.0 MPa^{1/2}.

According to the first embodiment, it is preferred that the solvent is a solvent containing a silicon atom.

According to the first embodiment, it is preferred that the silicone resin layer has a thickness of from 2 to 100 μm.

Further, according to the first embodiment, it is preferred that the support substrate is a glass plate.

According to a second embodiment of the present invention, there is provided a method for producing the glass laminate according to the first embodiment, the method comprising forming a layer containing the alkenyl group-containing organopolysiloxane (A) and the hydrogen polysiloxane (B) with a mixing molar ratio of the hydrosilyl groups in the hydrogen polysiloxane (B) to the alkenyl groups in the alkenyl group-containing organopolysiloxane (A) (number of mols of hydrosilyl groups/number of mols of alkenyl groups) of from 0.15/1 to 0.65/1 on one side of the support substrate; reacting the alkenyl group-containing organopolysiloxane (A) and the hydrogen polysiloxane (B) on the support substrate surface to form the silicone resin layer; and laminating the glass substrate on the surface of the silicone resin layer.

According to a third embodiment of the present invention, there is provided a method for producing an electronic device, the method comprising forming an electronic device component on the surface of the glass substrate of the glass laminate according to the first embodiment; and removing the support substrate and the silicone resin layer from the glass substrate of the glass laminate comprising the glass substrate and the electronic device component.

### Advantageous Effects of Invention

According to the present invention, it is possible to provide a glass laminate of which an increase of the peel strength between the glass substrate and the silicone resin layer is suppressed even after a high temperature heat treatment, and from which the glass substrate can readily be separated, and a method for producing it.

Further, according to the present invention, it is possible to provide a method for producing an electronic device using the glass laminate.

### BRIEF DESCRIPTION OF DRAWINGS

FIG. 1 is a cross-sectional view schematically illustrating the glass laminate according to an embodiment of the present invention.

FIG. 2(A), FIG. 2(B), FIG. 2(C) and FIG. 2(D) are cross-sectional views schematically illustrating the method for producing a component-provided glass substrate according to an embodiment of the present invention, in order of step.

### DESCRIPTION OF EMBODIMENTS

Now, the present invention will be described in detail with reference to drawings. However, the present invention is by no means restricted to such specific description, and various changes and modifications are possible without departing from the intension and the scope of the present invention.

The glass laminate of the present invention comprises a support substrate, a silicone resin layer and a glass substrate in this order. That is, it has a silicone resin layer between a support substrate and a glass substrate, and one side of the silicone resin layer is in contact with the support substrate and the other side is in contact with the glass substrate.

One of characteristics of the glass laminated of the present invention is that the silicone resin in the silicone resin layer is formed by using an alkenyl group-containing organopolysiloxane and a hydrogen polysiloxane mixed with a predetermined mixing ratio. More specifically, it is found that peel strength at the time of separation of the glass substrate is decreased by adjusting the mixing molar ratio of the hydrosilyl groups in the hydrogen polysiloxane to the alkenyl groups in the alkenyl group-containing organopolysiloxane to be within a predetermined range (number of mols of hydrosilyl groups/number of mols of alkenyl groups: 0.15/1 to 0.65/1).

As mentioned above, when the mixing molar ratio is adjusted so that the number of mols of the hydrosilyl groups is small, a decrease in the number of crosslinks is anticipated, and it is considered that the silicone resin layer will be flexible, whereby the adhesion of the silicone resin layer will improve and as a result, the glass substrate and the silicone resin layer will be bonded more firmly, and the releasability of the glass substrate will deteriorate. However, surprisingly, when the present inventors have formed a silicone resin layer with the above mixing molar ratio, the peel strength of the glass substrate decreased, and the releasability improved (that is, the glass substrate became readily separated).

The reason why the peel strength of the glass substrate decreases is considered as follows. That is, by adjusting the mixing molar ratio to be within a predetermined range, a non-crosslinked moiety of the alkenyl group-containing organopolysiloxane included in the network is present on the surface of the silicone resin layer. As a result, molecular chains of the alkenyl group-containing organopolysiloxane have high mobility on the surface, the surface energy on the silicone resin surface more decreases, and the releasability of the glass substrate improves.

Further, surprisingly, it was found that the silicone resin layer has a solvent resistance equal to that of a silicone resin layer formed according to an embodiment such that the mixing molar ratio (number of mols of hydrosilyl groups/number of mols of alkenyl groups) is about 1/1 as disclosed in Patent Document 1, and has excellent properties.

Further, in a case where a curable resin composition containing a solvent having a predetermined Hildebrand solubility parameter (SP value) is used as described hereinafter, such a curable resin composition has excellent application properties and improves the productivity. Further, flatness of the obtainable silicone resin layer will be more excellent, and lamination property of the glass substrate will be excellent.

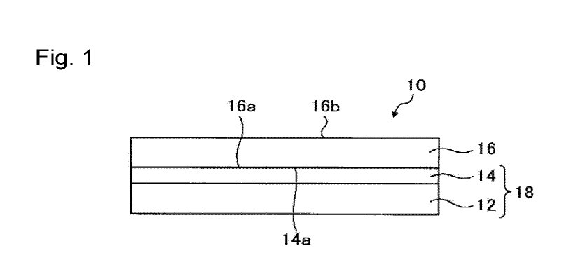

FIG. 1 is a cross-sectional view schematically illustrating the glass laminate according to an embodiment of the present invention.

As shown in FIG. 1, a glass laminate 10 is a laminate comprising a layer of a support substrate 12 and a layer of a glass substrate 16, and a silicone resin layer 14 therebetween. One surface of the silicone resin layer 14 is in contact with the layer of the support substrate 12 and the other side is in contact with a first principal plane 16a of the glass substrate 16.

The two-layer portion comprising the layer of the support substrate 12 and the silicone resin layer 14 reinforces the glass substrate 16 in a component-forming step of producing an electronic device component such as a liquid crystal panel. Further, the two-layer portion comprising the layer of the support substrate 12 and the silicone resin layer 14 preliminarily produced for production of the glass laminate 10 will be referred to as a silicone resin layer-provided support substrate 18.

The glass laminate 10 is used until the after-described component-forming step. That is, the glass laminate 10 is used until an electronic device component such as a liquid crystal display device is formed on a second principal plane 16b of the glass substrate 16. Then, the glass laminate on which the electronic device component is formed is separated into the silicone resin layer-provided support substrate 18 and an electronic device (component-provided glass substrate), and the silicone resin layer-provided support substrate 18 does not become a component constituting an electronic device. The silicone resin layer-provided support substrate 18 may be laminated with a new glass substrate 16 and recycled as a new glass laminate 10.

The interface between the support substrate 12 and the silicone resin layer 14 has a peel strength (x), and when a stress in a peeling direction exceeding the peel strength (x) is applied to the interface between the support substrate 12 and the silicone resin layer 14, the support substrate 12 and the silicone resin layer 14 are separated at their interface. Further, the interface between the silicone resin layer 14 and the glass substrate 16 has a peel strength (y), and when a stress in a peeling direction exceeding the peel strength (y) is applied to the interface between the silicone resin layer 14 and the glass substrate 16, the silicone resin layer 14 and the glass substrate 16 are separated at their interface.

In the glass laminate 10 (including the after-described electronic device component-provided laminate), the peel strength (x) is higher than the peel strength (y). Accordingly, in a case where a stress in a direction peeling the support substrate 12 and the glass substrate 16 is applied to the glass laminate 10, the glass laminate 10 of the present invention is separated into the glass substrate 16 and the silicone resin layer-provided support substrate 18 at the interface between the silicone resin layer 14 and the glass substrate 16.

The peel strength (x) is preferably sufficiently high as compared with the peel strength (y). An increase in the peel strength (x) means that the adhesion of the silicone resin layer 14 to the support substrate 12 is increased, and a higher adhesion than that to the glass substrate 16 can be maintained after a heat treatment.

In order to increase the adhesion of the silicone resin layer 14 to the support substrate 12, as described hereinafter, it is preferred to form the silicone resin layer 14 by curing (for example, curing by crosslinking) a layer of a curable resin composition containing predetermined components (that is, a coating film of the curable resin composition) on the support substrate 12. It is possible to form a silicone resin layer 14 bonded to the support substrate 12 with a high bonding strength, by the adhesive force at the time of curing.

On the other hand, the bonding strength of a cured product of an organopolysiloxane after curing to the glass substrate 16 is usually lower than the bonding strength generated at the time of the above curing. Accordingly, it is preferred that a curing treatment is applied to the layer of a curable resin composition on the support substrate 12 to form the silicone resin layer 14, and then the glass substrate 16 is laminated on the surface of the silicone resin layer 14 to produce the glass laminate 10.

Now, the respective layers (support substrate 12, glass substrate 16 and silicone resin layer 14) constituting the glass laminate 10 will be described in detail, and then methods for producing the glass laminate and an electronic device will be described in detail.

### <Support Substrate>

The support substrate 12 supports and reinforces the glass substrate 16 and in the after-described component-forming step (a step for producing an electronic device component), prevents deformation, scarring, breakage, etc. of the glass substrate 16 at the time of production of the electronic device component.

As the support substrate 12, for example, a glass plate, a plastic plate or a metal plate such as a SUS plate may be used. Usually, the component-forming step involves a heat treatment, the support substrate 12 is preferably formed of a material with a small difference in the linear expansion coefficient with the glass substrate 16, more preferably formed of the same material as the glass substrate 16, and the support substrate 12 is preferably a glass plate. Particularly, the support substrate 12 is preferably a glass plate made of the same glass material as the glass substrate 16.

The support substrate 12 may be thicker or thinner than the glass substrate 16. Preferably, the thickness of the support substrate 12 is selected depending upon the thickness of the glass substrate 16, the thickness of the silicone resin layer 14 and the thickness of the glass laminate 10. For example, in a case where the existing component-forming step is designed to treat a glass substrate having a thickness of 0.5 mm and the sum of the thickness of the glass substrate 16 and the thickness of the silicone resin layer 14 is 0.1 mm, a thickness of the support substrate 12 of 0.4 mm is selected. The thickness of the support substrate 12 is usually preferably from 0.2 to 5.0 mm.

In a case where the support substrate 12 is a glass plate, the thickness of the glass plate is preferably not less than 0.08 mm from such reasons that such a glass plate is easily handled and is hardly broken. Further, the thickness of the glass plate is preferably not more than 1.0 mm from such reasons that when the glass plate is separated after formation of the electronic device component, it is desired to have rigidity such that it does not break and is moderately bent.

The difference in the average linear expansion coefficient at from 25 to 300° C. between the support substrate 12 and the glass substrate 16 is preferably not more than 500×10⁻⁷/° C., more preferably not more than 300×10⁻⁷/° C., further preferably not more than 200×10⁻⁷/° C. If the difference is too large, the glass laminate 10 may be significantly warped, or the support substrate 12 and the glass substrate 16 may be separated at the time of heating and cooling in the component-forming step. When the material of the support substrate 12 is the same as the material of the glass substrate 16, such problems can be suppressed.

### <Glass Substrate>

Of the glass substrate 16, a first principal plane 16a is in contact with the silicone resin layer 14, and on a second principal plane 16b on the opposite side from the silicone resin layer 14, an electronic device component is provided.

The glass substrate 16 may be a commonly employed one, and for example, a glass substrate for a display device such as a LCD or an OLED may be mentioned. The glass substrate 16 is preferably one excellent in the chemical resistance and moisture resistance and having a low heat shrinkage. As an index to the heat shrinkage, the linear expansion coefficient as defined in JIS R3102 (revised in 1995) is employed.

If the linear expansion coefficient of the glass substrate 16 is high, various drawbacks are likely to be brought about since the component-forming step involves a heat treatment in many cases. For example, in a case where a TFT (thin film transistor) is to be formed on the glass substrate 16, when the glass substrate 16 on which a TFT was formed with heating, is cooled, slippage of the TFT may be significant due to heat shrinkage of the glass substrate 16.

The glass substrate 16 is obtained by melting a glass material and forming the molten glass into a plate. Such a forming method may be a conventionally employed method, and for example, the float process, the fusion method, the slot downdraw method, the Fourcault process or the cylinder process may be employed. Further, a particularly thin glass substrate 16 may be obtained by a method of heating glass preliminarily formed into a plate to a formable temperature, drawing it by means of e.g. stretching to make the glass plate thin (redraw process).

The type of glass of the glass substrate 16 is not particularly limited, and alkali-free borosilicate glass, borosilicate glass, soda lime glass, high-silica glass or other oxide-type glass containing silicon oxide as the main component is preferred. The oxide-type glass is preferably glass having a silicon oxide content as calculated as oxide of from 40 to 90 mass %.

As the glass of the glass substrate 16, glass suitable for the type of the electronic device component and its production method is employed. For example, a glass substrate for a liquid crystal panel is formed of glass (alkali-free glass) containing substantially no alkali metal component (however, usually containing an alkaline earth metal) since elution of the alkali metal component tends to influence the liquid crystal. As mentioned above, the glass for the glass substrate 16 is properly selected depending upon the type of the device applied and its production method.

The thickness of the glass substrate 16 is preferably not more than 0.3 mm, more preferably not more than 0.2 mm, further preferably not more than 0.15 mm, particularly preferably not more than 0.10 mm, from the viewpoint of reduction in thickness and/or weight saving of the glass substrate 16. When it is not more than 0.3 mm, the glass substrate 16 can have favorable flexibility. When it is not more than 0.15 mm, the glass substrate 16 can be wound into a roll.

Further, the thickness of the glass substrate 16 is preferably not less than 0.03 mm, from such reasons that such a glass substrate 16 is easily produced, and the glass substrate 16 can easily be handled.

Further, the glass substrate 16 may consist two or more layers, and in such a case, materials forming the respective layers may be the same or different. Further, in such a case, the “thickness of the glass substrate 16” means the total thickness of all the layers.

### <Silicone Resin Layer>

The silicone resin layer 14 prevents slippage of the glass substrate 16 until an operation of separating the glass substrate 16 and the support substrate 12 is carried out, and prevents the glass substrate 16 from being broken by the separation operation. The surface 14a to be in contact with the glass substrate 16 of the silicone resin layer 14 is removably bonded to the first principal plane 16a of the glass substrate 16. The silicone resin layer 14 is bonded to the first principal plane 16a of the glass substrate 16 by a weak bonding strength, and the peel strength (y) at their interface is lower than the peel strength (x) at the interface between the silicone resin layer 14 and the support substrate 12.

That is, when the glass substrate 16 and the support substrate 12 are separated, they are separated at the interface between the first principal plane 16a of the glass substrate 16 and the silicone resin layer 14, and the support substrate 12 and the silicone resin layer 14 are hardly separated at their interface. Thus, the silicone resin layer 14 has such surface properties that the silicone resin layer 14 is attached to the first principal plane 16a of the glass substrate 16 but can readily be separated from the glass substrate 16. That is, the silicone resin layer 14 is bonded to the first principal plane 16a of the glass substrate 16 with a certain bonding strength to prevent e.g. slippage of the glass substrate 16 and at the same time, it is bonded with a bonding strength to such an extent that the glass substrate 16 can readily be separated without breaking it, when the glass substrate 16 is to be separated. In the present invention, the property of the surface of the silicone resin layer 14 that it can readily be separated will be referred to as releasability. On the other hand, the first principal plane of the support substrate 12 and the silicone resin layer 14 are bonded with a bonding strength such that they can relatively hardly be separated.

The bonding strength at the interface between the silicone resin layer 14 and the glass substrate 16 may change between before and after formation of the electronic device component on the surface (second principal plane 16b) of the glass substrate 16 of the glass laminate 10 (that is, the peel strength (x) and the peel strength (y) may change). However, it is required that the peel strength (y) is lower than the peel strength (x) even after formation of the electronic device component.

In the glass laminate of the present invention, the peel strength at the interface between the glass substrate and the silicone resin layer is not more than 1.3 N/25 mm, preferably not more than 1.2 N/25 mm, more preferably not more than 1.1 N/25 mm, from the viewpoint such that breakage of the glass substrate is prevented when the glass substrate 16 and the support substrate 12 of the glass laminate are separated.

It is considered that the silicone resin layer 14 and the layer of the glass substrate 16 are bonded by a weak adhesive force or by a bonding strength by Van der Waals' force. In a case where the silicone resin layer 14 is formed and then the glass substrate 16 is laminated on its surface, when the silicone resin in the silicone resin layer 14 is sufficiently crosslinked so as not to exhibit an adhesive force, it is considered that the silicone resin layer 14 and the glass substrate 16 are bonded by a bonding strength by Van der Waals' force. However, the silicone resin in the silicone resin layer 14 has a certain weak adhesive force in many cases. For example, even in a case where the adhesion is extremely low, when the glass laminate 10 is produced and an electronic device component is formed on the laminate, it is considered that the silicone resin in the silicone resin layer 14 is attached to the glass substrate 16 surface e.g. by heating operation, and the bonding strength between the silicone resin layer 14 and the layer of the glass substrate 16 increases.

In some cases, the surface of the silicone resin layer 14 before lamination and the first principal plane 16a of the glass substrate 16 before lamination may be treated to weaken the bonding strength between them. It is possible to weaken the bonding strength at the interface between the silicone resin layer 14 and the layer of the glass substrate 16 and to make the peel strength (y) low by applying e.g. a non-adhesion treatment to the surfaces to be laminated, followed by lamination.

The silicone resin layer 14 is bonded to the surface of the support substrate 12 by a strong bonding strength such as an adhesive force or a cohesion. For example, as described above, by curing the layer of the curable resin composition on the surface of the support substrate 12, a silicone resin as a cured product is bonded to the support substrate 12 surface to achieve a high bonding strength. Further, it is also possible to increase the bonding strength between the support substrate 12 surface and the silicone resin layer 14 by a treatment to cause a strong bonding strength between the support substrate 12 surface and the silicone resin layer 14 (for example, a treatment by using a coupling agent).

The silicone resin layer 14 and the layer of the support substrate 12 being bonded by a high bonding strength means a high peel strength (x) at their interface.

The thickness of the silicone resin layer 14 is not particularly limited, and in either case where the curable resin composition contains a solvent or not, the thickness of the silicone resin layer 14 to be formed is preferably from 2 to 100 μm, more preferably from 3 to 50 μm, further preferably from 7 to 20 μm. When the thickness of the silicone resin layer 14 is within such a range, even if bubbles for foreign matters may present between the silicone resin layer 14 and the glass substrate 16, deformation defects of the glass substrate 16 can be suppressed. Further, if the silicone resin layer 14 is relatively thick, even if foreign matters are present, they can be prevented from becoming bubbles. Further, if the silicone resin layer 14 is too thick, time and the material will be required to form such a silicone resin layer 14, and such being economically inefficient, and the heat resistance may decrease in some cases. Further, if the silicone resin layer 14 is too thin, if foreign matters are present between the silicone resin layer 14 and the glass substrate 16, bubbles are likely to form. The thickness of the silicone resin layer 14 may be adjusted by the concentration of the resin components in the curable resin composition, or the amount of the coating liquid applied to the support substrate.

The silicone resin layer 14 may consist of two or more layers. In such a case, the “thickness of the silicone resin layer 14” means the total thickness of all the layers.

The silicone resin contained in the silicone resin layer 14 is a cured product (crosslinked cured product) obtained by reacting an alkenyl group-containing organopolysiloxane (A) and a hydrogen polysiloxane (B) having a hydrosilyl group (Si-H group). The silicone resin preferably forms a three-dimensional network structure.

The alkenyl group-containing organopolysiloxane (A) (hereinafter sometimes referred to simply as polysiloxane (A)) is an organopolysiloxane having an alkenyl group.

The number average molecular weight of the polysiloxane (A) is not particularly limited, and is from 500 to 50,000 in many cases, and with a view to more readily separating the glass substrate 16, in the present invention, it is preferably from 500 to 9,000, more preferably from 1,000 to 8,000, further preferably from 1,500 to 6,000.

The number average molecular weight is a number average molecular weight measured by GPC (gel permeation chromatography) and calculated as standard polystyrene.

The polysiloxane (A) may be in a straight chain or in a branched chain, and in view of more excellent releasability of the glass substrate 16, it is preferably in a straight chain (for example, linear).

The alkenyl group containing in the polysiloxane (A) is not particularly limited and may, for example, be a vinyl group (an ethenyl group), an allyl group (2-propenyl group), a butenyl group, a pentenyl group or a hexynyl group, and among them, preferred is a vinyl group in view of excellent heat resistance.

The number of the alkenyl group contained in the polysiloxane (A) is not particularly limited, however, in view of more excellent releasability of the glass substrate 16, it is preferably 2 or more per one molecule, more preferably from 2 to 120, further preferably from 2 to 100.

Further, as a group other than the alkenyl group contained in the polysiloxane (A), an alkyl group (particularly an alkyl group having not more than 4 carbon atoms) may be mentioned.

The position of the alkenyl group in the polysiloxane (A) is not particularly limited, and may be the terminal and/or the side chain of the polysiloxane (A).

In a case where the polysiloxane (A) is in a straight chain, the alkenyl group may be present in either of the following unit M or unit D, or may be present in both of the unit M and the unit D. In view of the curing rate, it is preferably present in at least the unit M, and it is preferably present in both of the two units M.

The units M and D are examples of the basic structural units of the organopolysiloxane, and the unit M is a monofunctional siloxane unit having three organic groups bonded, and the unit D is a bifunctional siloxane unit having two organic groups bonded. In the siloxane unit, in the siloxane bond, which is a bond having two silicon atoms bonded via one oxygen atom, the number of the oxygen atom per one silicon atom is regarded as ½, and the oxygen atom is represented as O_{1/2} in the formula.

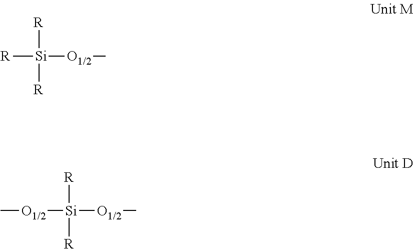

As the unit M having the alkenyl group, preferred is an embodiment in which one of the above Rs is the alkenyl group, and the other Rs are alkyl groups.

Further, as the unit D having the alkenyl group, preferred is an embodiment in which either one of the above Rs is the alkenyl group, and other R is an alkyl group.

The hydrogen polysiloxane (B) (hereinafter sometimes referred to simply as polysiloxane (B)) is an organopolysiloxane having a hydrosilyl group (a hydrogen atom bonded to a silicon atom).

The number average molecular weight of the polysiloxane (B) is not particularly limited, and with a view to more readily separating the glass substrate 16, it is preferably from 500 to 9,000, more preferably from 1,000 to 8,000, further preferably from 1,500 to 6,000.

The polysiloxane (B) may be in a straight chain or in a branched chain, and in view of more excellent releasability of the glass substrate 16, it is preferably in a straight chain (for example, linear).

The number of the hydrosilyl group (hydrogen atom bonded to a silicon atom) contained in the polysiloxane (B) is not particularly limited, however, in view of more excellent releasability of the glass substrate 16, it is preferably 2 or more per one molecule, more preferably from 2 to 120, further preferably from 2 to 100.

Further, as a group other than the hydrosilyl group contained in the polysiloxane (B), an alkyl group (particularly an alkyl group having not more than 4 carbon atoms) may be mentioned.

The position of the hydrosilyl group in the polysiloxane (B) is not particularly limited, and may be the terminal and/or the side chain of the polysiloxane (B).

In a case where the polysiloxane (B) is in a straight chain, the hydrosilyl group may be present in either of the above unit M or unit D, or may be present in both of the unit M and the unit D.

As the mixing ratio of the polysiloxane (B) to the polysiloxane (A), the mixing molar ratio of the hydrosilyl groups in the polysiloxane (B) to the alkenyl groups in the polysiloxane (A) (number of mols of hydrosilyl groups/number of mols of alkenyl groups) is from 0.15/1 to 0.65/1, and in view of more excellent releasability of the glass substrate 16, it is preferably not less than 0.15/1 and less than 0.60/1, more preferably not less than 0.25/1 and less than 0.60/1, particularly preferably from 0.25/1 to 0.50/1. The above mixing molar ratio represents the molar ratio of the number of mols of the hydrosilyl groups to the number of mols of the alkenyl groups.

If the mixing molar ratio exceeds 0.65/1, the releasability of the glass substrate 16 after the heat treatment tends to be poor. Further, if the mixing molar ratio is less than 0.15/1, the crosslink density of the cured product will significantly decrease, a cured product having a sufficient hardness will not be obtained, and the lamination properties of the glass substrate 16 tend to be poor. Further, along with the decrease of the crosslink density of the cured product, the heat resistance may decrease.

The silicone resin contained in the silicone resin 14 is a cured product obtained by reaction (for example, addition reaction) of the polysiloxane (A) and the polysiloxane (B).

The reaction may be carried out, as the case requires, in the presence of a catalyst (for example, a hydrosilylation catalyst).

As the catalyst, a platinum group metal catalyst is preferably used. The platinum group metal catalyst may, for example, be a platinum, palladium or rhodium catalyst, and is particularly preferably a platinum catalyst in view of economical efficiency and reactivity. As the platinum catalyst, a known catalyst may be used. Specifically, a platinum fine powder, platinum black, chloroplatinic acid such as hexachloroplatinic (IV) acid or tetrachloroplatinic acid, platinum (IV) chloride, an alcohol compound or an aldehyde compound of chloroplatinic acid, or an olefin complex, alkenyl siloxane complex or carbonyl complex of platinum, may, for example, be mentioned.

The amount of the catalyst (preferably the platinum group metal catalyst) used is not particularly limited, and is preferably from 2 to 400 ppm, more preferably from 5 to 300 ppm, particularly preferably from 8 to 300 ppm by the mass ratio based on the total mass of the polysiloxane (A) and the polysiloxane (B).

The method for forming the silicone resin layer 14 is not particularly limited, and usually, a method of applying a curing treatment to a layer of a composition containing the polysiloxane (A) and the polysiloxane (B) may be mentioned. The method for forming the silicone resin layer will be described in detail in the after-described [Glass laminate and its production method]

### [Glass Laminate and its Production Method]

The glass laminate 10 of the present invention is, as described above, a laminate comprising a support substrate 12 and a glass substrate 16 and a silicone resin layer 14 interposed therebetween.

The method for producing the glass laminate 10 of the present invention is not particularly limited, and to obtain a glass laminate in which the peel strength (x) at the interface between the support substrate 12 and the silicone resin layer 14 is higher than the peel strength (y) at the interface between the silicone resin layer 14 and the glass substrate 16, preferred is a method of reacting the polysiloxane (A) and the polysiloxane (B) on the support substrate 12 surface to form the silicone resin layer 14. That is, a layer containing the polysiloxane (A) and the polysiloxane (B) in the above mixing molar ratio is formed on the surface of the support substrate 12, the polysiloxane (A) and the polysiloxane (B) are reacted on the support substrate 12 surface to form the silicone resin layer 14 (for example, a layer of the crosslinked silicone resin) and then the glass substrate 16 is laminated on the silicone resin surface of the silicone resin layer 14 to produce the glass laminate 10.

It is considered that when the polysiloxane (A) and the polysiloxane (B) are cured on the support substrate 12 surface, the silicone resin and the support substrate 12 are bonded by the interaction with the support substrate 12 surface at the time of the curing reaction, whereby the peel strength between the silicone resin and the support substrate 12 surface becomes high. Accordingly, even when the glass substrate 16 and the support substrate 12 are made of the same material, a difference in the peel strength between the silicone resin layer 14 and both of them can be provided.

Now, a step of forming a layer containing the polysiloxane (A) and the polysiloxane (B) on the surface of the support substrate 12 and reacting (for example, crosslinking) the polysiloxane (A) and the polysiloxane (B) on the support substrate 12 surface to form the silicone resin layer 14, will be referred to as a resin layer-forming step, and a step of laminating the glass substrate 16 on the silicone resin surface of the silicone resin layer 14 to form the glass laminate 10 will be referred to as a laminating step, and procedures of the respective steps will be described below.

### (Resin Layer-Forming Step)

In the resin layer-forming step, a layer containing the polysiloxane (A) and the polysiloxane (B) is formed on the surface of the support substrate 12, and the polysiloxane (A) and the polysiloxane (B) are crosslinked on the support substrate 12 surface to form the silicone resin layer 14. The polysiloxane (A) and the polysiloxane (B) are mixed so that the above-described mixing molar ratio (number of mols of hydrosilyl groups/number of mols of alkenyl groups) will be from 0.15/1 to 0.65/1.

To form a layer containing the polysiloxane (A) and the polysiloxane (B) on the support substrate 12, it is preferred to use a curable resin composition containing the polysiloxane (A) and the polysiloxane (B) in the above mixing molar ratio, and to apply the composition to the support substrate 12 to form a layer of the composition. The thickness of the layer of the composition may be controlled e.g. by adjusting the amount of application of the composition.

The curable resin composition preferably contains a solvent in order that the application properties of the composition will be good and application is conducted at a higher speed, a thinner silicone resin layer can be formed, leveling properties will improve by the decrease of the viscosity, and the flatness of the obtained coating film will improve.

The solvent is not particularly limited and may, for example, be butyl acetate, heptane, 2-heptanone, 1-methoxy-2-propanol acetate, toluene, xylene, THF, chloroform, dialkylpolysiloxane or a saturated hydrocarbon.

The dynamic viscosity of the solvent is not particularly limited, and in view of more excellent flatness of the silicone resin layer 14, it is preferably not more than 23 mm²/s, more preferably not more than 12 mm²/s, further preferably not more than 6 mm²/s. The lower limit is not particularly limited, and is not less than 0.1 mm²/s in many cases.

The solvent is preferably dried at 100° C. or above, in order that it will not remain on the surface of the silicone resin layer formed, and heating at a temperature of the boiling point of the solvent or higher is preferred. However, even if the solvent remaining on the silicone resin layer surface is transferred to the surface of the glass substrate which is once laminated on the silicone resin layer and then separated, the properties of the surface can be changed so that the water contact angle will be small by applying e.g. an ordinary pressure plasma treatment to the surface of the glass substrate.

The boiling point of the solvent is not particularly limited, and in view of more excellent flatness of the silicone resin layer 14, it is preferably from 30 to 280° C., more preferably from 50 to 230° C. The boiling point means a value under atmospheric pressure.

The Hildebrand solubility parameter (SP value) (hereinafter sometimes referred to as “Hildebrand SP value” which is a solubility parameter of the solvent used is not particularly limited, and for example, a solvent with a Hildebrand SP value of not more than 18 MPa^{1/2} may be mentioned, and in the present invention, in view of more excellent flatness of the silicone resin layer 14 obtained, a solvent with a Hildebrand SP value of not more than 14.0 MPa^{1/2} is preferably used. Such a solvent is excellent in compatibility with the polysiloxane (A) and the polysiloxane (B), will not roughen the surface of a layer of the curable resin composition when the layer is formed, will volatilize, and as a result, will achieve more excellent flatness of the silicone resin layer 14.

The Hildebrand SP value of the solvent is preferably not more than 14.0 MPa^{1/2}, more preferably not more than 13.5 MPa^{1/2}, further preferably not more than 13.0 MPa^{1/2}. The lower limit is not particularly limited, and in view of the compatibility with the polysiloxane (A) and the polysiloxane (B), it is preferably not less than 10.0 MPa^{1/2}.

The Hildebrand solubility parameter (SP value) may be represented as follows by the Hansen SP value (δD, δP, δH).

Hildebrand SP value=square root of (δD²+δP²+δH²)

The Hansen solubility parameters are represented by three parameters δD for dispersion, δP for polarity and δH for hydrogen bonding, based on the solubility parameter developed by Hildebrand, in three dimensions. δD represents an effect from dispersion forces between molecules, δP represents an effect from dipolar intermolecular force between molecules, and δH represents an effect from hydrogen bonds between molecules.

The definition and calculation of the Hansen solubility parameters are disclosed in Hansen Solubility Parameters: A Users Handbook, Charles M. Hansen (CRC Press, 2007). Further, by computer software Hansen Solubility Parameters in Practice (HSPiP), the Hansen solubility parameters can be easily estimated. In the present invention, for actual calculation of the Hansen SP values [δD, δP, δH], software prepared by Hansen et al., HSPiP version 4.1 is employed.

As a specific example, the Hildebrand solubility parameter (SP value) of octamethylcyclotetrasiloxane is 12.9 from the Hansen SP values [δD, δP, δH=12.8, 1.3, 1].

As the solvent having the above Hildebrand SP value, in view of more excellent compatibility with the polysiloxane (A) and the polysiloxane (B) and in view of more excellent flatness of the silicone resin layer 14, preferred is a solvent containing a silicon atom, and preferred is a dialkylpolysiloxane (preferably, dimethylpolysiloxane (polydimethylpolysiloxane)).

The dialkylpolysiloxane may be any of in a straight chain, in a branched chain or cyclic, preferably in a straight chain or cyclic, more preferably cyclic (for example, cyclic dialkylpolysiloxane). Further, the dialkylpolysiloxane preferably has a viscosity or boiling point within the above-described range.

As specific examples of the dialkyl polysiloxane, for example, a cyclic dimethylpolysiloxane represented by the following formula (1) or a straight chain dimethylpolysiloxane represented by the formula (2) may be mentioned.

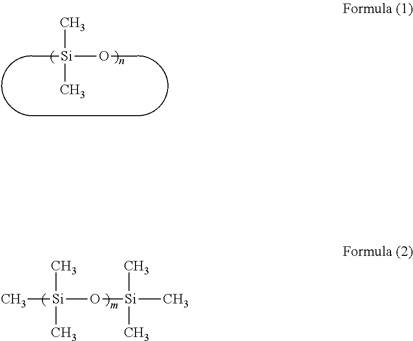

In the above formula (1), n is an integer of from 3 to 9.

In the above formula (2), m is an integer of from 3 to 9.

As compounds represented by such formulae, for example, octamethylcyclotetrasiloxane (Hildebrand SP value: 12.9), hexamethylcyclotrisiloxane, decamethylcyclopentasiloxane (Hildebrand SP value 11.5), octamethyltrisiloxane and decamethyltetrasiloxane (Hildebrand SP value: 12.9) may be mentioned.

In a case where the curable resin composition contains the solvent, in view of application properties, the total amount of the polysiloxane (A) and the polysiloxane (B) is preferably from 10 to 95 mass %, more preferably from 20 to 90 mass %, further preferably from 30 to 70 mass %, particularly preferably from 30 to 50 mass % based on the total mass of the curable resin composition.

The curable resin composition may contain, as the case requires, a component other than the polysiloxane (A), the polysiloxane (B) and the solvent.

For example, the above-described catalyst may be contained.

Further, for the curable resin composition, it is preferred to use an activity inhibiting agent (a compound also called a reaction suppressant, a retardant or the like) having a function to suppress the catalytic activity for the purpose of adjusting the catalytic activity together with the catalyst, in combination. Such an activity inhibiting agent may, for example, be an organic nitrogen compound, an organic phosphorous compound, an acetylene compound, an oxime compound or an organic chlorine compound. Further, as the case requires, within a range not to impair the effects of the present invention, an inorganic filler such as silica, calcium carbonate or iron oxide may, for example, be incorporated.

The method of applying the curable resin composition containing the polysiloxane (A) and the polysiloxane (B) to the support substrate 12 surface is not particularly limited, and a known method may be used. For example, a spray coating method, a die coating method, a spin coating method, a dip coating method, a roll coating method, a bar coating method, a screen printing method or a gravure coating method may be mentioned.

Then, as the case requires, a drying treatment to remove the solvent may be carried out. The method of the drying treatment is not particularly limited, and a method of removing the solvent under reduced pressure or a heating method at a temperature at which curing of the polysiloxane (A) and the polysiloxane (B) will not proceed may be mentioned.

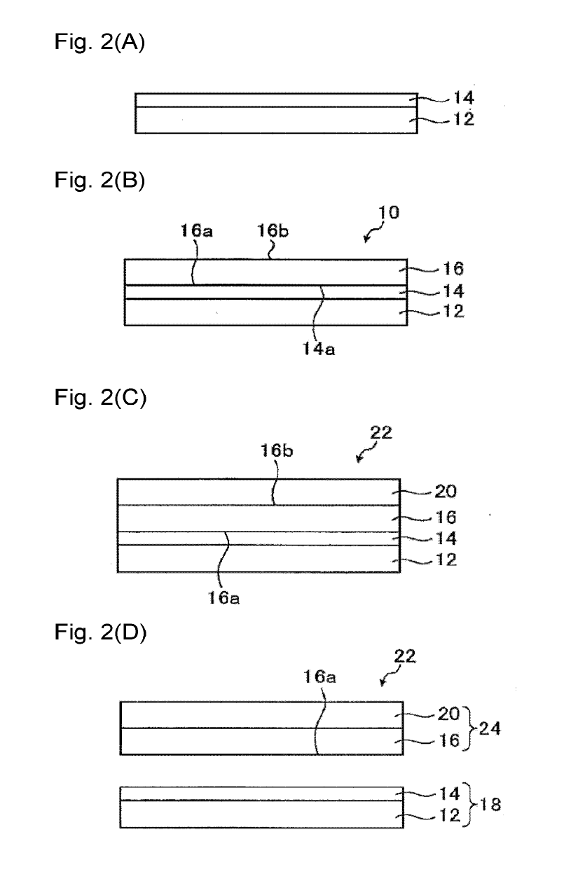

Then, a curing treatment is applied to the layer of the curable resin composition on the support substrate 12, so that the polysiloxane (A) and the polysiloxane (B) in the layer are reacted (specifically, crosslinked) to form the silicone resin layer 14. More specifically, as shown in FIG. 2(A), the silicone resin layer 14 is formed on at least one surface of the support substrate 12 in this step.

As a curing (for example, crosslinking) method, usually heat curing is employed.

The temperature at which the polysiloxane (A) and the polysiloxane (B) are reacted is not particularly limited within a range where the heat resistance of the silicone resin layer 14 will improve and the peel strength (y) after lamination with the glass substrate 16 may be controlled as above, and is preferably from 80 to 250° C., more preferably from 120 to 230° C. Further, the heating time is usually preferably from 10 to 120 minutes, more preferably from 30 to 60 minutes.

The layer of the curable resin composition may be pre-cured (preliminary curing) and then post-cured (main curing). By the pre-curing, a silicone resin layer 14 which is more excellent in the heat resistance can be obtained.

### (Laminating Step)

The laminating step is a step of laminating the glass substrate 16 on the silicone resin surface of the silicone resin layer 14 obtained in the above resin layer-forming step to obtain the glass laminate 10 comprising the support substrate 12, the silicone resin layer 14 and the glass substrate 16 in this order. More specifically, as shown in FIG. 2(B), the silicone resin layer 14 and the glass substrate 16 are laminated so that a surface 14a on the opposite side from the support substrate 12 of the silicone resin layer 14 and a first principal plane 16a of the glass substrate 16 having the first principal plane 16a and a second principal plane 16b are in contact with each other, to obtain the glass laminate 10.

The method of laminating the glass substrate 16 on the silicone resin layer 14 is not particularly limited, and a known method may be employed.

For example, a method of overlaying the glass substrate 16 on the surface of the silicone resin layer 14 under ordinary pressure may be mentioned. Further, as the case requires, after the glass substrate 16 is overlaid on the surface of the silicone resin layer 14, the glass substrate 16 may be contact-bonded to the silicone resin layer 14 by a roll or a press. By the contact-bonding by a roll or a press, bubbles included between the silicone resin layer 14 and the layer of the glass substrate 16 will relatively easily be removed.

It is more preferred to contact-bond the silicone resin layer 14 and the glass substrate 16 by a vacuum laminating method or a vacuum pressing method, whereby inclusion of bubbles can be suppressed, and favorable adhesion can be secured. Contact-bonding in vacuum is advantageous also in that even if small bubbles remain, the bubbles will not grow by heating, and distortion defects of the glass substrate 16 are less likely to be brought about.

When the glass substrate 16 is laminated, it is preferred that the surface of the glass substrate 16 to be in contact with the silicone resin layer 14 is sufficiently cleaned, and the glass substrate 16 is laminated in a highly clean environment. The cleaner, the better the flatness of the glass substrate 16.

After the glass substrate 16 is laminated, as the case requires, a heat treatment may be carried out. By the heat treatment, the adhesion of the glass substrate 16 laminated to the silicone resin layer 14 will improve and an appropriate peel strength (y) can be achieved, whereby slippage or the like of the electronic device component will hardly occur in the after-described component-forming step, thus improving the productivity of an electronic device.

As the heat treatment conditions, optimum conditions are properly selected depending upon the type of the silicone resin layer 14 used, and in order to achieve a more appropriate peel strength (y) between the glass substrate 16 and the silicone resin layer 14, it is preferred to carry out the heat treatment at a temperature of 200° C. or higher (preferably from 200 to 400° C.) for 5 minutes or longer, preferably from 5 to 30 minutes).

Formation of the silicone resin layer 14 is not limited to the above method.

For example, in a case where a support substrate 12 made of a material having a higher adhesion to the silicone resin surface than the glass substrate 16 is used, the above curable resin composition containing the polysiloxane (A) and the polysiloxane (B) is cured on a certain removable surface to produce a film of the silicone resin, and the film is interposed between the glass substrate 16 and the support substrate 12 and laminated at the same time.

Further, in a case where the adhesion by the silicone resin is sufficiently low to the glass substrate 16 and is sufficiently high to the support substrate 12, a layer of the curable resin composition containing the polysiloxane (A) and the polysiloxane (B) may be cured between the glass substrate 16 and the support substrate 12 to form the silicone resin layer 14.

Further, even in a case where the support substrate 12 is made of the same glass material as the glass substrate 16, the peel strength from the silicon resin layer 14 may be increased by applying a treatment to increase the adhesion of the support substrate 12 surface. For example, a chemical method (primer treatment) of chemically improving the fixation power e.g. with a silane coupling agent, a physical method of increasing surface active groups such as a flame treatment or a mechanical treatment method of increasing the roughness of the surface thereby to increase indentations, such as sand blasting, may, for example, be mentioned.

### (Glass Laminate)

The glass laminate 10 of the present invention can be used for various application, for example, for production of an electronic component such as a display device panel, solar battery (PV), thin film secondary battery or semiconductor wafer having a circuit formed on its surface, as described hereinafter. For such applications, the glass laminate 10 is exposed (for example, for 5 minutes or longer) to high temperature conditions (for example, 350° C. or higher) in many cases.

Here, a display device panel includes a LCD, an OLED, electronic paper, a plasma display panel, a field emission panel, a quantum dot LED panel and a MEMS (Micro Electro Mechanical Systems) shutter panel.

### [Electronic Device and its Production Method]

In the present invention, by using the above-described glass laminate, an electronic device comprising a glass substrate and an electronic device component (hereinafter sometimes referred to as “a component-provided glass substrate”) is produced.

The method for producing an electronic device is not particularly limited, and in view of excellent productivity of electronic devices, preferred is a method in which an electronic device component is formed on the glass substrate in the glass laminate to produce an electronic device component-provided laminate, and the obtained electronic device component-provided laminate is separated into an electronic device (component-provided glass substrate) and a silicone resin layer-provided support substrate at the interface between the silicone resin layer and the glass substrate as the peel surface.

Hereinafter, a step of forming an electronic device component on the glass substrate in the glass laminate to produce an electronic device component-provided laminate will be referred to as a component-forming step, and a step of separating the electronic device component-provided laminate into a component-provided glass substrate and a silicone resin layer-provided support substrate at the interface between the silicone resin layer and the glass substrate as the peel surface, will be referred to as a separating step.

Now, materials and procedure in the respective steps will be described in detail.

### (Component-Forming Step)

The component-forming step is a step of forming an electronic device component on the glass substrate 16 in the glass laminate 10 obtained in the above laminating step. More specifically, as shown in FIG. 2(C), an electronic device component 20 is formed on the second principal plane 16b (exposed surface) of the glass substrate 16 to obtain an electronic device component-provided laminate 22.

First, the electronic device component (also called a functional device) 20 used in this step will be described in detail, and then the procedure of the step will be described in detail.

### (Electronic Device Component (Functional Device))

The electronic device component 20 is a component constituting at least a part of an electronic device formed on the glass substrate 16 in the glass laminate 10. More specifically, the electronic device component 20 may, for example, be a component to be used for e.g. an electronic component such as a display device panel, a solar battery, a thin film secondary battery or a semiconductor wafer having a circuit formed on its surface (for example, a display device component, a solar battery component, a thin film secondary battery component or a circuit for an electronic component).

For example, as a solar battery component, for a silicon type, a transparent electrode of e.g. tin oxide for a positive electrode, a silicon layer represented by p layer/i layer/n layer, or a metal for a negative electrode may, for example, be mentioned, and in addition, components corresponding to a compound type, a dye-sensitizing type, a quantum dot type, etc. may, for example, be mentioned.

As the thin film secondary battery component, for a lithium ion type, a transparent electrode of e.g. a metal or a metal oxide for a positive electrode and a negative electrode, a lithium compound for an electrolyte layer, a metal for a current collector layer, or a resin as a sealing layer may, for example, be mentioned, and in addition, components corresponding to a nickel metal hydride type, a polymer type, a ceramic electrolyte type, etc. may, for example, be mentioned.

Further, as the circuit for an electronic component, for a CCD and a CMOS, a metal for a conductive part, silicon oxide or silicon nitride for an insulating part may, for example, be mentioned, and in addition, components corresponding to a sensor such as a pressure sensor or an acceleration sensor, a rigid printed board, a flexible printed board, a rigid flexible printed board, etc., may, for example, be mentioned.

### (Procedure of Steps)

The method for producing the electronic device component-provided laminate 22 is not particularly limited, and depending upon the type of the component constituting the electronic device component, by a conventional method, an electronic device component 20 is formed on the second principal plane 16b of the glass substrate 16 in the glass laminate 10.

The electronic device component 20 may not only be the whole component to be finally formed on the second principal plane 16b of the glass substrate 16 (hereinafter referred to as “the whole component”) but also a part of the whole component (hereinafter referred to as “partial component”). The partial component-provided glass substrate separated from the silicone resin layer 14 may be formed into a whole component-provided glass substrate (corresponding to the after-described electronic device) in the subsequent step.

Further, on the whole component-provided glass substrate separated from the silicone resin layer 14, another electronic device component may be formed on the peel surface (first principal plane 16a). Further, it is also possible to assemble a whole component-provided laminate and then separate the support substrate 12 from the whole component-provided laminate to produce an electronic device. Further, it is also possible to unite two whole component-provided laminates, and then separate two support substrates 12 from an assembly of the whole component-provided laminates to produce an assembly comprising two partial component-provided glass substrates.

For example, with reference to production of an OLED as an example, various layer formation and treatment steps such as a step of forming a transparent electrode, to form an organic EL structure on the opposite side from the silicone resin layer 14 of the glass substrate 16 in the glass laminate 10 (corresponding to the second principal plane 16b of the glass substrate 16), a step of forming on the surface on which the transparent electrode was formed, by vapor deposition, a hole injection layer, a hole transport layer, a luminous layer, an electron transport layer, etc., a step of forming a back electrode, and a step of sealing using a sealing plate, are conducted. As such layer formation and treatment steps, specifically, for example, a film formation treatment, a deposition treatment, an adhesion treatment of a sealing plate may, for example, be mentioned.

Further, for example, in the case of production of TFT-LCD, a TFT-forming step of forming a thin film transistor (TFT) by pattern forming on a metal film, a metal oxide film or the like formed by a conventional film forming method such as a CVD method or a sputtering method, by using a resist liquid, on the second principal plane 16b of the glass substrate 16 in the glass laminate 10, a CF-forming step of forming a color filter (CF) on the second principal plane 16b of the glass substrate 16 of another glass laminate 10 by using a resist liquid for pattern forming, a bonding step of laminating the TFT-provided laminate obtained in the TFT-forming step and the CF-provided laminate obtained in the CF-forming step, etc., are conducted.

In the TFT-forming step and the CF-forming step, by known photolithography technique, etching technique or the like, the TFT or the CF is formed on the second principal plane 16b of the glass substrate 16. On that occasion, a resist liquid is used as a coating liquid for pattern forming.

Further, before formation of the TFT or CF, as the case requires, the second principal plane 16b of the glass substrate 16 may be cleaned. As a cleaning method, known dry cleaning or wet cleaning may be employed.

In the bonding step, the thin film transistor-formed surface of the TFT-provided laminate and the color filter-formed surface of the CF-provided laminate are disposed to face each other and bonded by a sealing agent (for example, an ultraviolet-curable sealing agent for cell formation). Then, into a cell formed by the TFT-provided laminate and the CF-provided laminate, a liquid crystal material is injected. As a method of injecting a liquid crystal material, for example, a vacuum injection method or a dropping injection method may be employed.

### (Separating Step)

The separating step is, as shown in FIG. 2(D), a step of separating the electronic device component-provided laminate 22 obtained in the above component-forming step into a glass substrate 16 on which the electronic device component 20 is laminated (component-provided glass substrate) and the support substrate 12 at the interface between the silicone resin layer 14 and the glass substrate 16 as the peel surface to obtain a component-provided glass substrate (electronic device) 24 comprising the electronic device component 20 and the glass substrate 16.

In a case where the electronic device component 20 on the glass substrate 16 when separated is a part of the whole constituting component required, the rest of constituting components may be formed on the glass substrate 16 after separation.

The method of separating the glass substrate 16 and the support substrate 12 is not particularly limited. Specifically, for example, a sharp knife-form object is inserted into the interface between the glass substrate 16 and the silicone resin layer 14 to impart a trigger for separation, and then a mixed fluid of water and compressed air is blown to separate them. Preferably, the electronic device component-provided laminate 22 is set on a platen so that the support substrate 12 faces upward and the electronic device component 20 faces downward, the electronic device component 20 side is vacuum-contacted to the platen, and in such a state, a knife is inserted into the interface between the glass substrate 16 and the silicone resin layer 14. Then, the support substrate 12 side is adsorbed by a plurality of vacuum suction pads, and the vacuum suction pads are lifted up in order from the vicinity of a point where the knife is inserted, whereupon an air layer is formed at the interface between the silicone resin layer 14 and the glass substrate 16 and in a cohesive failure surface of the silicone resin layer 14, the air layer spreads over the entire interface and cohesive failure surface, and the support substrate 12 can readily be separated. In a case where the support substrates 12 are laminated on both sides of the electronic device component-provided laminate 22, separation of the glass substrate 16 and the support substrate 12 on one side and separation of the glass substrate 16 and the support substrate 12 on the other side may be conducted sequentially.

Further, the support substrate 12 may be laminated with a new glass substrate to produce the glass laminate 10 of the present invention.

When the component-provided glass substrate 24 is separated from the electronic device component-provided laminate 22, electrostatic adsorption of fragments of the silicone resin layer 14 on the component-provided glass substrate 24 can further be suppressed by blowing by an ionizer or by controlling the humidity.

The above-described method for producing a component-provided glass substrate 24 is particularly suitable for production of a small-sized display device used for a mobile terminal such as a portable phone or a PDA. The display device is mainly a LCD or an OLED, and the LCD includes a TN type, a STN type, a FE type, a TFT type, a MIM type, an IPS type, a VA type and the like. Basically both display devices of a passive matrix type and an active matrix type are applicable.

The component-provided glass substrate 24 produced by the above method may, for example, be a display device panel comprising a glass substrate and a display device component, a solar battery comprising a glass substrate and a solar battery component, a thin film secondary battery comprising a glass substrate and a thin film secondary battery component, and an electronic component comprising a glass substrate and an electronic device component. The display device panel includes a liquid crystal panel, an organic EL panel, a plasma display panel, a field emission panel and the like.

### EXAMPLES

Now, the present invention will be described in further detail with reference to Examples (A), (B), (C) and the like. However, it should be understood that the present invention is by no means restricted to such specific Examples.

In the following Examples 1 to 8 and Comparative Examples 1 to 2, as the support substrate, a glass plate (240 mm×240 mm×0.5 mm in thickness, linear expansion coefficient: 38×10⁻⁷/° C., “AN100”, tradename, manufactured by Asahi Glass Company, Limited) made of alkali-free borosilicate glass was used.

### Example A

### Example 1

First, a support substrate having a thickness of 0.5 mm was cleaned by washing with pure water and further by UV cleaning.

Then, an alkenyl group-containing organopolysiloxane (number average molecular weight: 2,000, number of alkenyl groups: 2 or more) (100 parts by mass) and a hydrogen polysiloxane (number average molecular weight: 2,000, number of hydrosilyl groups: 2 or more) (6.7 parts by mass) were blended. The mixing molar ratio of the hydrosilyl groups in the hydrogen polysiloxane to the alkenyl groups in the alkenyl group-containing organopolysiloxane (number of mols of hydrosilyl groups/number of mols of alkenyl groups) was 0.4/1. Further, a catalyst (platinum catalyst) was added in an amount of 300 mass ppm based on the total mass (100 parts by mass) of the alkenyl group-containing organopolysiloxane and the hydrogen polysiloxane. This liquid will be referred to as a curable resin composition X. The curable resin composition X was applied to a first principal plane of the support substrate by a die coater to form a layer containing an uncured alkenyl group-containing organopolysiloxane and hydrogen polysiloxane on the support substrate.

Then, the support substrate having the layer formed thereon was heated in the air at 140° C. for 3 minutes and then heat-cured in the air at 230° C. for 20 minutes to form a silicone resin layer having a thickness of 10 μm on the first principal plane of the support substrate. The flatness of the silicone resin layer was favorable.

Then, a glass substrate and the silicone resin layer surface of the support substrate were bonded by vacuum pressing at room temperature to obtain a glass laminate A.

On that occasion, as the glass substrate, a glass plate (200 mm×200 mm×0.2 mm in thickness, linear expansion coefficient: 38×10⁻⁷/° C., “AN100”, tradename, manufactured by Asahi Glass Company, Limited) formed of alkali-free borosilicate glass was used.

In the obtained glass laminate A, each of the support substrate and the glass substrate was contact-bonded to the silicone resin layer without bubbles, and there was no distortion defect. In the glass laminate A, the peel strength at the interface between the silicone resin layer and the layer of the support substrate was higher than the peel strength at the interface between the layer of the glass substrate and the silicone resin layer.

Then, the glass laminate A was subjected to a heat treatment in a nitrogen atmosphere at 350° C. for 10 minutes and cooled to room temperature, whereupon no change in the appearance such as separation of the support substrate and the glass substrate, bubbling of the silicone resin layer and whitening was confirmed on the glass laminate A.

The glass laminate A after the heat treatment at 350° C. for 10 minutes was subject to the following peel test to measure the peel strength (N/25 mm) of the glass substrate.

To measure the peel strength, a glass laminate A having a width of 25 mm and a length of 70 mm was prepared, and using autograph AG-20/50kNXDplus (manufactured by Shimadzu Corporation), the glass substrate and the silicone resin layer were separated.

On that occasion, a stainless steel knife having a thickness of 0.1 mm was inserted into the interface between the glass substrate and the silicone resin layer to form a notch for separation, and then the glass substrate was completely fixed, and the support substrate was lifted up to measure the strength. The lifting rate was 30 mm/min.

Based on a point where the load was detected being 0, the peel strength at a point lifted up 2.0 mm from the point above was taken as the measured value. The peel strength at that point was 0.53 N/25 mm.

### Example 2

A glass laminate B was obtained in the same manner as in Example 1 except that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.6/1.

Flatness of the obtained silicone resin layer was favorable.

In the obtained glass laminate B, each of the support substrate and the glass substrate was contact-bonded to the silicone resin layer without bubbles, and there was no distortion defect. Further, in the glass laminate B, the peel strength at the interface between the silicone resin layer and the layer of the support substrate was higher than the peel strength at the interface between the layer of the glass substrate and the silicone resin layer.

Further, the glass laminate B was subjected to the same heat treatment as in Example 1, whereupon no change in the appearance such as separation of the support substrate and the glass substrate, bubbling of the silicone resin layer and whitening was confirmed on the glass laminate B.

Further, after the heat treatment, the peel test was conducted in the same manner as in Example 1, whereupon the peel strength was 0.88 N/25 mm.

### Example 3

A glass laminate C was obtained in the same manner as in Example 1 except that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.25/1.

Flatness of the obtained silicone resin layer was favorable.

In the obtained glass laminate C, each of the support substrate and the glass substrate was contact-bonded to the silicone resin layer without bubbles, and there was no distortion defect. Further, in the glass laminate C, the peel strength at the interface between the silicone resin layer and the layer of the support substrate was higher than the peel strength at the interface between the layer of the glass substrate and the silicone resin layer.

Further, the glass laminate C was subjected to the same heat treatment as in Example 1, whereupon no change in the appearance such as separation of the support substrate and the glass substrate, bubbling of the silicone resin layer and whitening was confirmed on the glass laminate C.

Further, after the heat treatment, the peel test was conducted in the same manner as in Example 1, whereupon the peel strength was 0.45 N/25 mm.

### Example 4>

A glass laminate D was obtained in the same manner as in Example 1 except that octamethylcyclotetrasiloxane (manufactured by Shin-Etsu Chemical Co., Ltd., KF-994, dynamic viscosity (25° C.): 2.3 mm²/s, boiling point: 175° C., Hildebrand solubility parameter (SP value): 12.9 MPa^{1/2}) was further added as a solvent to the curable resin composition X.

The amount of octamethylcyclotetrasiloxane used was such an amount that the total amount of the alkenyl group-containing organopolysiloxane, the hydrogen polysiloxane and the catalyst was 40 mass % based on the total amount of the composition.

Flatness of the obtained silicone resin layer was favorable.

In the obtained glass laminate D, each of the support substrate and the glass substrate was contact-bonded to the silicone resin layer without bubbles, and there was no distortion defect. Further, in the glass laminate D, the peel strength at the interface between the silicone resin layer and the layer of the support substrate was higher than the peel strength at the interface between the layer of the glass substrate and the silicone resin layer.

Further, the glass laminate D was subjected to the same heat treatment as in Example 1, whereupon no change in the appearance such as separation of the support substrate and the glass substrate, bubbling of the silicone resin layer and whitening was confirmed on the glass laminate D.

Further, after the heat treatment, the peel test was conducted in the same manner as in Example 1, whereupon the peel strength was 0.60 N/25 mm.

At the time of application by a die coater, the curable resin composition X could be applied at a rate 3 times higher than in Example 1. On that occasion, the amount of discharge of the curable resin composition X was adjusted so that a 10 μm silicone resin layer would be formed.

### Example 5

A glass laminate E was obtained in the same manner as in Example 4 except that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.6/1.

Flatness of the obtained silicone resin layer was favorable.

In the obtained glass laminate E, each of the support substrate and the glass substrate was contact-bonded to the silicone resin layer without bubbles, and there was no distortion defect. Further, in the glass laminate E, the peel strength at the interface between the silicone resin layer and the layer of the support substrate was higher than the peel strength at the interface between the layer of the glass substrate and the silicone resin layer.

Further, the glass laminate E was subjected to the same heat treatment as in Example 1, whereupon no change in the appearance such as separation of the support substrate and the glass substrate, bubbling of the silicone resin layer and whitening was confirmed on the glass laminate E.

Further, after the heat treatment, the peel test was conducted in the same manner as in Example 1, whereupon the peel strength was 0.77 N/25 mm.

At the time of application by a die coater, the curable resin composition X could be applied at a rate 3 times higher than in Example 1. On that occasion, the amount of discharge of the curable resin composition X was adjusted so that a 10 μm silicone resin layer would be formed.

### Example 6

A glass laminate F was obtained in the same manner as in Example 4 except that an alkenyl group-containing organopolysiloxane (number average molecular weight: 10,000, number of alkenyl groups: 2 or more) was used instead of the alkenyl group-containing organopolysiloxane (number average molecular weight: 2,000, number of alkenyl groups: 2 or more). The amount of the alkenyl group-containing organopolysiloxane was adjusted so that the mixing molar ratio of the hydrosilyl groups in the hydrogen polysiloxane to the alkenyl groups in the alkenyl group-containing organopolysiloxane would be the same as in Example 1.

Flatness of the obtained silicone resin layer was favorable.

In the obtained glass laminate F, each of the support substrate and the glass substrate was contact-bonded to the silicone resin layer without bubbles, and there was no distortion defect. Further, in the glass laminate F, the peel strength at the interface between the silicone resin layer and the layer of the support substrate was higher than the peel strength at the interface between the layer of the glass substrate and the silicone resin layer.

Then, the glass laminate F was subjected to the same heat treatment as in Example 1, whereupon no change in the appearance such as separation of the support substrate and the glass substrate, bubbling of the silicone resin layer and whitening was confirmed on the glass laminate F.

Further, after the heat treatment, the peel test was conducted in the same manner as in Example 1, whereupon the peel strength was 0.79 N/25 mm.

### Example 7

A glass laminate I was obtained in the same manner as in Example 1 except that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.15/1.

Flatness of the obtained silicone resin layer was favorable.

In the obtained glass laminate I, each of the support substrate and the glass substrate was contact-bonded to the silicone resin layer without bubbles, and there was no distortion defect. Further, in the glass laminate I, the peel strength at the interface between the silicone resin layer and the layer of the support substrate was higher than the peel strength at the interface between the layer of the glass substrate and the silicone resin layer.

Further, the glass laminate I was subjected to the same heat treatment as in Example 1, whereupon no change in the appearance such as separation of the support substrate and the glass substrate, bubbling of the silicone resin layer and whitening was confirmed on the glass laminate I.

Further, after the heat treatment, the peel test was conducted in the same manner as in Example 1, whereupon the peel strength was 0.40 N/25 mm.

### Example 8

A glass laminate J was obtained in the same manner as in Example 1 except that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.65/1.

Flatness of the obtained silicone resin layer was favorable.

In the obtained glass laminate J, each of the support substrate and the glass substrate was contact-bonded to the silicone resin layer without bubbles, and there was no distortion defect. Further, in the glass laminate J, the peel strength at the interface between the silicone resin layer and the layer of the support substrate was higher than the peel strength at the interface between the layer of the glass substrate and the silicone resin layer.

Further, the glass laminate J was subjected to the same heat treatment as in Example 1, whereupon no change in the appearance such as separation of the support substrate and the glass substrate, bubbling of the silicone resin layer and whitening was confirmed on the glass laminate J.

Further, after the heat treatment, the peel test was conducted in the same manner as in Example 1, whereupon the peel strength was 1.00 N/25 mm.

### Comparative Example 1

A glass laminate G was obtained in the same manner as in Example 1 except that an alkenyl group-containing organopolysiloxane (number average molecular weight: 10,000, number of alkenyl groups: 2 or more) was used instead of the alkenyl group-containing organopolysiloxane (number average molecular weight: 2,000, number of alkenyl groups: 2 or more) and that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.9/1.

Flatness of the obtained silicone resin layer was favorable.

In the obtained glass laminate G, each of the support substrate and the glass substrate was contact-bonded to the silicone resin layer without bubbles, and there was no distortion defect. Further, in the glass laminate G, the peel strength at the interface between the silicone resin layer and the layer of the support substrate was higher than the peel strength at the interface between the layer of the glass substrate and the silicone resin layer.

Further, the glass laminate G was subjected to the same heat treatment as in Example 1, whereupon no change in the appearance such as separation of the support substrate and the glass substrate, bubbling of the silicone resin layer and whitening was confirmed on the glass laminate G.

Further, after the heat treatment, the peel test was conducted in the same manner as in Example 1, whereupon the peel strength was 1.57 N/25 mm, which was high as compared with Examples.

### Comparative Example 2

A glass laminate H was obtained in the same manner as in Example 1 except that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.76/1.

Flatness of the obtained silicone resin layer was favorable.

In the obtained glass laminate H, each of the support substrate and the glass substrate was contact-bonded to the silicone resin layer without bubbles, and there was no distortion defect. Further, in the glass laminate H, the peel strength at the interface between the silicone resin layer and the layer of the support substrate was higher than the peel strength at the interface between the layer of the glass substrate and the silicone resin layer.

Further, the glass laminate H was subjected to the same heat treatment as in Example 1, whereupon no change in the appearance such as separation of the support substrate and the glass substrate, bubbling of the silicone resin layer and whitening was confirmed on the glass laminate H.

Further, after the heat treatment, the peel test was conducted in the same manner as in Example 1, whereupon the peel strength was 1.34 N/25 mm, which was high as compared with Examples.

### <Evaluation of Workability>

Workability of each of the glass laminates in Examples 1 to 8 and Comparative Examples 1 and 2 was evaluated as follows.

A stainless steel knife was inserted 10 mm into an edge of the interface between the silicone resin layer and the glass substrate in the glass laminate (width: 25 mm, length: 70 mm) obtained in each of Examples and Comparative Examples, and the stainless steel knife was moved 50 mm along the length direction. Workability was evaluated based on the standards o: the stainless steel knife smoothly moved without breaking the glass substrate, and x: the stainless steel knife hardly moved, and breakage of the glass substrate occurred. The results are shown in the column “workability” in Table 1.

Whether the stainless steel knife smoothly moved or not relates to the peel strength between the silicone resin layer and the glass substrate, and if the peel strength is high, the stainless steel knife hardly moves.

The specifications and the evaluation results in Examples and Comparative Examples are shown in Table 1. In the column “solvent” in Table 1, “nil” means that the curable resin composition X contains no solvent, and “contained” means that the curable resin composition X contains octamethylcyclotetrasiloxane.

TABLE 1

| | | Number average | | Number of mols of | | | Application |
|---|---|---|---|---|---|---|---|
| | Glass | molecular weight of | | hydrosilyl groups/number | Peel strength | | rate |
| | laminate | polysiloxane (A) | Solvent | of mols of alkenyl groups | [N/25 mm] | Workability | (times) |
| Example 1 | A | 2,000 | Nil | 0.4 | 0.53 | ∘ | 1 |
| Example 2 | B | 2,000 | Nil | 0.6 | 0.88 | ∘ | — |
| Example 3 | C | 2,000 | Nil | 0.25 | 0.45 | ∘ | — |
| Example 4 | D | 2,000 | Contained | 0.4 | 0.60 | ∘ | 3 |
| Example 5 | E | 2,000 | Contained | 0.6 | 0.77 | ∘ | 3 |
| Example 6 | F | 10,000 | Contained | 0.4 | 0.79 | ∘ | — |
| Example 7 | I | 2,000 | Nil | 0.15 | 0.40 | ∘ | — |
| Example 8 | J | 2,000 | Nil | 0.65 | 1.00 | ∘ | — |
| Comp. Ex. 1 | G | 10,000 | Nil | 0.9 | 1.57 | x | — |
| Comp. Ex. 2 | H | 2,000 | Nil | 0.76 | 1.34 | x | — |

As shown in Table 1, in a case where the mixing molar ratio of the polysiloxane (B) to the polysiloxane (A) (number of mols of hydrosilyl groups/number of mols of alkenyl groups) satisfied the range of the present invention, the peel strength was low, and the glass substrate was easily separated.

On the other hand, in Comparative Example 1 in which the mixing molar ratio was about the mixing molar ratio (number of mols of hydrosilyl groups/number of mols of alkenyl groups) disclosed in Patent Document 1, the peel strength was high, and the glass substrate was hardly separated.

By comparison between Example 1 and Example 4, in Example 4 in which the curable resin composition contained the solvent, the application rate was high, and excellent productivity was achieved.

### Example B

### (Preparation of Sample B-1)

0.5 g of a curable resin composition Y obtained by adjusting the amount of the hydrogen polysiloxane so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.5/1 in the curable resin composition X in Example 1, was dropped on a polytetrafluoroethylene film (PTFE film). Then, the PTFE film having the curable resin composition Y formed thereon was left at rest on a hot plate heated at 150° C. for 4 minutes and further heat-cured in an oven at 220° C. for 20 minutes to form a silicone resin layer on the PTFE film thereby to obtain a silicone resin layer of sample B-1.

### (Preparation of Sample B-2)

A silicone resin layer of sample B-2 was obtained in the same manner as in Preparation of sample B-1 except that the amount of the hydrogen polysiloxane was adjusted so that the mixing molar ratio of the hydrosilyl groups in the hydrogen polysiloxane to the alkenyl groups in the alkenyl group-containing organopolysiloxane (number of mols of hydrosilyl groups/number of mols of alkenyl groups) would be 0.9/1.

### (Evaluation of Chemical Resistance)

30 mL of an aqueous tetramethylammonium hydroxide solution (concentration: 2.5 mass %) was put in a PFA petri dish, sample B-1 was dipped therein for 5 hours and then taken out, and the remaining aqueous tetramethylammonium hydroxide solution was recovered to obtain a measurement sample.

Then, by ICP-MS (inductively coupled plasma mass spectrometer) (Agilent 8800, manufactured by Agilent Technologies), the amount of silicon atoms in the measurement sample was measured.

Sample B-2 was also subjected to the same evaluation.

In both of samples B-1 and B-2, the amounts of silicon atoms in the measurement samples were at the same level, and there was no difference in the chemical resistance between the silicone resin layer in sample B-1 and the silicone resin layer in sample B-2. That is, the solvent resistance of the silicone resin layer obtained with the mixing molar ratio within the range of the present invention was at the same level as that of a silicone resin layer formed with a mixing molar ratio (number of mols of hydrosilyl groups/number of mols of alkenyl groups) to be about 1/1 as disclosed in Patent Document 1, and no decrease in the solvent resistance was observed.

### Example C

### Example 9

In this Example, an OLED is produced by using the glass laminate A obtained in Example 1.

On a second principal plane of the glass substrate in the glass laminate A, by plasma CVD method, films of silicon nitride, silicon oxide and amorphous silicon are formed in this order. Then, by an ion doping apparatus, low concentration boron is injected into the amorphous silicon layer, and in a nitrogen atmosphere, a heat treatment is carried out to conduct dehydrogenation treatment. Then, by a laser annealing apparatus, a treatment to crystallize the amorphous silicon layer is carried out.

Then, by etching employing photolithography and an ion doping apparatus, low concentration phosphorous is injected into the amorphous silicon layer, and a N type and P type TFE area is formed. Then, on the second principal plane side of the glass substrate, a silicon oxide film is formed by plasma CVD method to form a gate insulating film, then a film of molybdenum is formed by sputtering method, and a gate electrode is formed by etching employing photolithography.

Then, high concentration boron and phosphorous are injected into desired areas of the N type and the P type, respectively, by photolithography and an ion doping apparatus, to form a source area and a drain area. Then, on the second principal plane side of the glass substrate, a silicon oxide film is formed by plasma CVD method to form an interlayer insulating film, an aluminum film is formed by sputtering method, and a TFT electrode is formed by etching employing photolithography.

Then, in a hydrogen atmosphere, a heat treatment is carried out to conduct hydrogenation treatment, and a silicon nitride film is formed by plasma CVD method to form a passivation layer. Then, on the second principal plane side of the glass substrate, an ultraviolet curable resin is applied, and by photolithography, a planarizing layer and a contact hole are formed. Then, a film of indium tin oxide is formed by sputtering method, and a picture electrode is formed by etching employing photolithography.

Then, by deposition method, on the second principal plane side of the glass substrate, a film of 4,4′,4″-tris(3-methylphenyl phenylamino)triphenylamine as a hole injection layer, a film of bis[(N-naphthyl)-N-phenyl]benzidine as a hole transport layer, a film of a mixture of 8-quinolinol aluminum complex (Alq₃) and 40 vol % of 2,6-bis[4-[N-(4-methoxyphenyl)-N-phenyl]aminostyryl]naphthalene-1,4-dicarbonitrile (BSN-BCN) as a luminous layer, and a film of Alq₃ as an electron transport layer are formed in this order. Then, a film of aluminum is formed by sputtering method, and a counter electrode is formed by etching employing photolithography. Then, another glass substrate is bonded to the second principal plane side of the glass substrate by means of an ultraviolet curable adhesive layer for sealing. By the above procedure, an organic EL structure is formed on the glass substrate. The glass laminate A having an organic EL structure on the glass substrate (hereinafter referred to as panel A) is the electronic device component-provided laminate of the present invention.

Then, the sealed side of the panel A was vacuum-contacted to a platen, and a stainless steel knife with a thickness of 0.1 mm is inserted into the interface between the glass substrate and the resin layer at a corner of the panel A, to impart a trigger for separation to the interface between the glass substrate and the resin layer. Further, the support substrate surface of the panel A was adsorbed by vacuum suction pads, and the vacuum suction pads are lifted up. Here, insertion of the knife is carried out while a static-eliminated fluid from an ionizer (manufactured by KEYENCE CORPORATION) is blown to the interface. Then, while a static-eliminated fluid is continuously blown from the ionizer toward the formed gap, and while water is poured into the front of the separation, the vacuum suction pads are lifted up. As a result, the resin layer-provided support substrate can be separated while only the glass substrate having the organic EL structure formed thereon remains on the platen.

Then, the separated glass substrate is cut by a laser cutter or a scribe and break method into a plurality of cells, and the glass substrate having the organic EL structure formed thereon and a counter substrate are combined, and by a module-forming step, an OELD is prepared. The OLED thus obtained has no problems in its property.

### INDUSTRIAL APPLICABILITY

According to the present invention, it is possible to provide a glass laminate of which an increase of the peel strength between a glass substrate and a silicone resin layer is suppressed even after an electronic device component is formed on the glass substrate under high temperature conditions, and from which the glass substrate can readily be separated, and a method for producing it. Such a glass laminate is useful as a component for producing an electronic device.

This application is a continuation of PCT Application No. PCT/JP2015/081996, filed on Nov. 13, 2015, which is based upon and claims the benefit of priority from Japanese Patent Application No. 2014-236517 filed on Nov. 21, 2014. The contents of those applications are incorporated herein by reference in their entireties.

### REFERENCE SYMBOLS

10: glass laminate, 12: support substrate, 14: silicone resin layer, 14a: first principal plane of silicone resin layer, 16: glass substrate, 16a: first principal plane of glass substrate, 16b: second principal plane of glass substrate, 18: silicone resin layer-provided support substrate, 20: electronic device component, 22: electronic device component-provided laminate, and 24: component-provided glass substrate

1. A glass laminate comprising a support substrate, a silicone resin layer and a glass substrate in this order, with a peel strength at the interface between the support substrate and the silicone resin layer higher than the peel strength at the interface between the silicone resin layer and the glass substrate,
wherein a silicone resin in the silicone resin layer is a cured product obtained by reacting an alkenyl-group containing organopolysiloxane (A) and a hydrogen polysiloxane (B) having a hydrosilyl group, and the mixing molar ratio of the hydrosilyl groups in the hydrogen polysiloxane (B) to the alkenyl groups in the alkenyl group-containing organopolysiloxane (A) (that is, number of mols of hydrosilyl groups/number of mols of alkenyl groups) is from 0.15/1 to 0.65/1.

2. The glass laminate according to claim 1, wherein the alkenyl group-containing organopolysiloxane (A) has a number average molecular weight of from 500 to 9,000.

3. The glass laminate according to claim 1, wherein the silicone resin layer is a layer obtained by applying a curing treatment to a layer obtained by applying a curable resin composition containing the alkenyl group-containing organopolysiloxane (A) and the hydrogen polysiloxane (B) with a mixing molar ratio of the hydrosilyl groups in the hydrogen polysiloxane (B) to the alkenyl groups in the alkenyl group-containing organopolysiloxane (A) (number of mols of hydrosilyl groups/number of mols of alkenyl groups) of from 0.15/1 to 0.65/1.

4. The glass laminate according to claim 3, wherein the curable resin composition further contains a solvent.

5. The glass laminate according to claim 4, wherein the solvent has a boiling point of from 30 to 280° C.

6. The glass laminate according to claim 4, wherein the Hildebrand solubility parameter (SP value) of the solvent is not more than 14.0 MPa^{1/2}.

7. The glass laminate according to claim 4, wherein the solvent is a solvent containing a silicon atom.

8. The glass laminate according to claim 1, wherein the silicone resin layer has a thickness of from 2 to 100 μm.

9. The glass laminate according to claim 1, wherein the support substrate is a glass plate.

10. A method for producing the glass laminate according to claim 1, the method comprising forming a layer containing the alkenyl group-containing organopolysiloxane (A) and the hydrogen polysiloxane (B) with a mixing molar ratio of the hydrosilyl groups in the hydrogen polysiloxane (B) to the alkenyl groups in the alkenyl group-containing organopolysiloxane (A) (number of mols of hydrosilyl groups/number of mols of alkenyl groups) of from 0.15/1 to 0.65/1 on one side of the support substrate; reacting the alkenyl group-containing organopolysiloxane (A) and the hydrogen polysiloxane (B) on the support substrate surface to form the silicone resin layer; and laminating the glass substrate on the surface of the silicone resin layer.

11. A method for producing an electronic device, the method comprising forming an electronic device component on the surface of the glass substrate of the glass laminate of claim 1; and removing the support substrate and the silicone resin layer from the glass substrate of the glass laminate comprising the glass substrate and the electronic device component.
